(19) United States
(12) Patent Application Publication
(10) Pub. No.: US 2022/0236304 A1
(43) Pub. Date: Jul. 28, 2022

(54) Probe Head Including a Guide Plate with Angled Holes to Determine Probe Flexure Direction

(71) Applicant: FormFactor, Inc., Livermore, CA (US)

(72) Inventors: Sterling Tadashi Collins, Oakland, CA (US); Jason William Cosman, Livermore, CA (US); Lich Thanh Tran, San Jose, CA (US); Vinh-Lam Olivier Buu, Burlingame, CA (US)

(21) Appl. No.: 17/587,898

(22) Filed: Jan. 28, 2022

Related U.S. Application Data
(60) Provisional application No. 63/142,965, filed on Jan. 28, 2021.

(51) Int. Cl. G01R 1/073

(52) U.S. Cl. CPC G01R 1/07357

(57) ABSTRACT

Vertical probe arrays having angled guide plates are provided. With this configuration, the probes can be straight conductors (when mechanically undeformed) and the mechanical bias provided by the angled guide plates can ensure the probes have a well-defined deformation when the probe array make contact to the device under test. This allows the use of straight conductors as probes without suffering from probe shorting and mechanical interference caused by straight probes buckling in unpredictable directions when vertically compressed.

### CROSS REFERENCE TO RELATED APPLICATIONS

This application claims priority from U.S. Provisional Patent Application 63/142,965 filed Jan. 28, 2021, which is incorporated herein by reference.

### FIELD OF THE INVENTION

This invention relates to probe arrays for making temporary electrical contact to a device or circuit under test.

### BACKGROUND

Wafer test for high-density integrated circuits requires small contact probes that are tightly packed together. These probes are generally aligned between wafer pads and space transformer pads through a pair of guide plates. A cost-efficient probe design uses straight sections of conductors as probes, which can be easily inserted through both guide plates. When the contact pins are pressed against the wafer pads, the sections of conductor in between the two guide plates buckle off their respective axes. However, in such an arrangement, compressed probes can bow in any direction (see FIG. 1), leading to mechanical interference and electrical shorts between adjacent probes.

On FIG. 1, 102 is the device under test, 104 is the space transformer connecting the probe array to the rest of the test equipment, 106 is the upper guide plate, 108 is the lower guide plate, and 110 and 112 are two vertical probes of the probe array. Under axial compression (e.g., caused by moving the device under test closer to the probe head as shown by 120 on FIG. 1), buckling of probes 110 and 112 can occur in any direction, such as 114 and 116 on FIG. 1, which would create an electrical short between these two probes.

Thus a probe array of straight conductors would be prone to shorting between adjacent probes, especially with the closely spaced probe arrays that are often required to test complex electrical devices, such as integrated circuits.

One approach for dealing with this issue is to use probes having a defined mechanical motion. For example, a curved vertical probe will tend to bend along its preexisting curve when vertically compressed. However, this approach imposes significant additional mechanical design constraints on the probes and adds complexity to the assembly process. Another approach for dealing with this issue is considered in U.S. Pat. No. 6,417,684. In this example, a third guide plate is used to mechanically bias the probes to provide a preferred direction for probe deformation under vertical compression. However, through experimentation and analysis, we determined that the third guide plate does not consistently enforce the desired flexural mode in the probes. Accordingly, it would be an advance in the art to provide improved mechanical biasing for vertical probes.

### SUMMARY

In this work angled holes in the upper and/or lower guide plates are used to provide this mechanical bias. Here the lower guide plate is the guide plate closest to the device under test and the upper guide plate is the guide plate closest to the test instrument.

Several advantages are provided.

1) The consistent flexural mode enforced on the probes prevents electrical short circuits and unwanted mechanical interactions between probes during operation.
2) The moment resulting from the flexure provides retention of the probes by friction, independent of any lateral offset between the upper and lower guide plates.
3) The enforced contact between the probes and the lower guide plate as a result of this mechanical moment provides a kinematic constraint that increases the positional accuracy of the probe tips.
4) This probe head architecture enables the use of low-cost, simple straight conductors as probes.

### BRIEF DESCRIPTION OF THE DRAWINGS

FIG. 1 shows a problem that can occur when straight conductors are used in a probe array.

FIG. 2 shows a first embodiment of the invention.

FIG. 3 shows a second embodiment of the invention.

FIG. 4 shows a third embodiment of the invention.

FIG. 5 shows a presently preferred way of making guide plates with angled holes.

FIG. 6 shows a conventional way of making guide plates with angled holes.

FIG. 7 shows further details relating to the geometry of guide plates with angled holes.

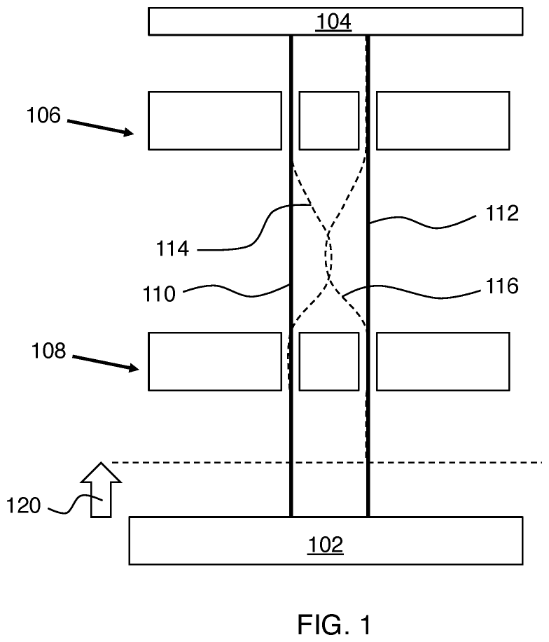

### DETAILED DESCRIPTION

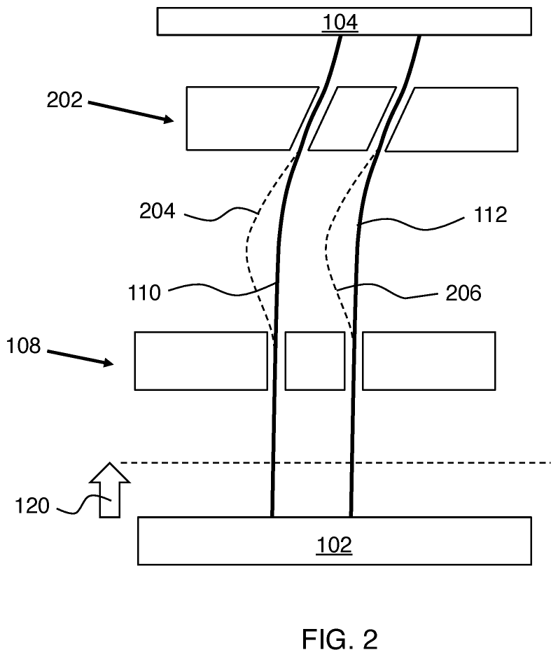

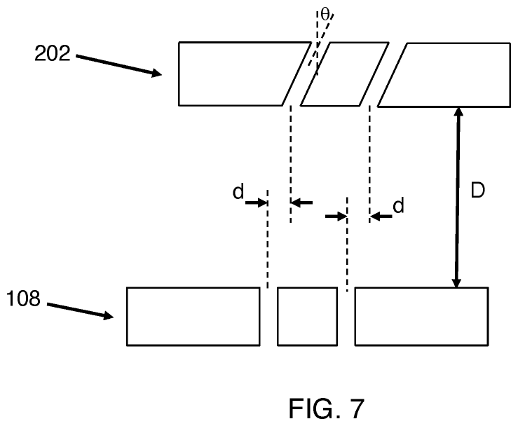

FIG. 2 shows a first embodiment of the invention. Here upper guide plate 202 has angled holes. Probes 110 and 112 pass through guide plates 202 and 108 and are bent by the angled holes in guide plate 202 and by the guide plate offset (d on FIG. 7) into curved shapes as shown (without these mechanical constraints, probes 110 and 112 would be straight conductors). Under axial compression (e.g., caused by moving the device under test closer to the probe head as shown by 120 on FIG. 2), further bending of probes 110 and 112 occurs in a defined buckling direction, schematically shown by 204 and 206 on FIG. 2, which prevents an electrical short between these two probes. Here a vertical probe array is a probe array where probes are substantially in axial compression when probing a device under test. This is in contrast to a cantilever probe array, where probe deformation is lateral to the probe axis when probing a device under test.

Accordingly, an embodiment of the invention is a vertical probe array including an upper guide plate, a lower guide plate and an array of vertical probes. Each of the vertical probes passes though corresponding holes in the upper and lower guide plates, each of the vertical probes is mechanically elastic and electrically conductive, and each of the probes is a straight conductor when not subjected to a mechanical force. Such conductors can be wires, microfabricated components, or any other electrical conductor with suitable mechanical properties. The holes of at least one of the upper and lower guide plates are angled at a bias angle configured to provide a mechanical bias to the probes sufficient to define a buckling direction of each probe when the array of vertical probes is vertically compressed.

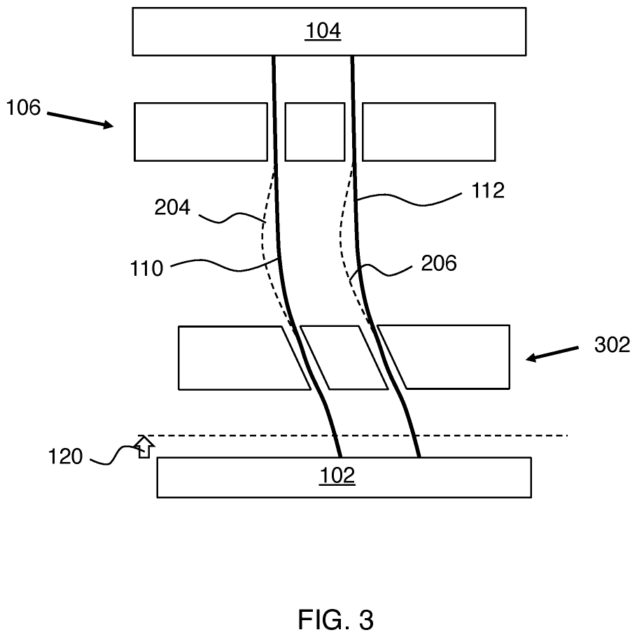

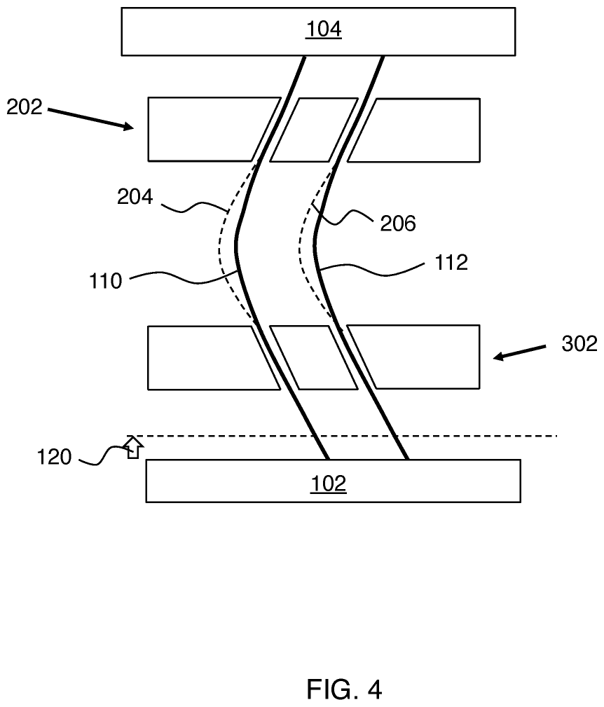

Angled holes can be used on the upper guide plate (FIG. 2), the lower guide plate (FIG. 3), or both (FIG. 4). The presently preferred embodiment is to have angled holes at the upper guide plate and straight holes at the lower guide plate. On FIG. 3, the lower guide plate 302 is angled, and the probe array operates as described above. On FIG. 4, the upper guide plate 202 and the lower guide plate 302 are angled, and the probe array operates as described above.

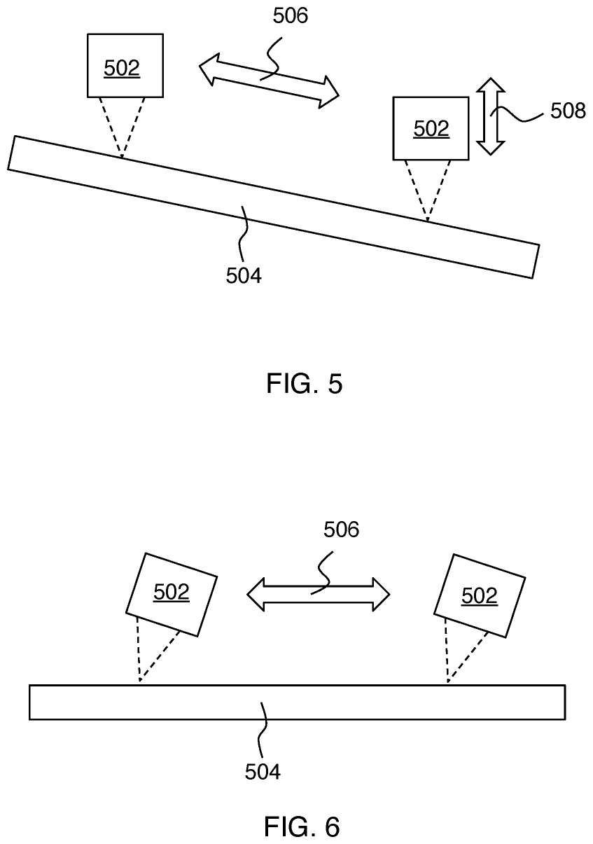

FIG. 5 shows a presently preferred way of making guide plates with angled holes. Here a laser drilling tool 502 is used where the work piece 504 is fixtured at an angle as shown. In such cases, the laser drilling tool 502 is operated so as to maintain a constant working distance between the laser focusing objective and the work piece, e.g., by moving the laser head vertically (508) as needed under automatic control while the laser head moves horizontally (506) to automatically keep the working distance the same while drilling all the holes.

FIG. 6 shows a more conventional way of making guide plates with angled holes. Here the laser drilling head 502 is tilted. Although this approach can be simpler than the approach of FIG. 5, the drilling performance may not be as good as provided by the approach of FIG. 5 (in terms of hole precision, uniformity etc.), and angled guide plates for probe arrays typically benefit from better holes made by the approach of FIG. 5.

FIG. 7 shows further details relating to the geometry of guide plates with angled holes. Here D is the spacing between guide plates, d is the guide plate offset, and θ is the hole angle. Simulation studies show that all probes buckle in the same direction provided the hole angle θ is larger than a critical angle, which depends on the ratio of the offset (d) between the upper and lower holes corresponding to the same probe and the spacing between the guide plates (D). As one design example, if d/D=0.03, the critical angle is 0.7 degrees. Simulations to determine critical angles for other d/D ratios and/or for other guide plate configurations (e.g., FIGS. 3 and 4) can be performed according to principles described herein by workers of ordinary skill in this art.

Accordingly, some embodiments of the invention have a bias angle of 1 degree or larger.

In some embodiments of the invention, the bias angle is above a critical angle that is determined by a ratio of guide plate offset (e.g., d on FIG. 7) to guide plate spacing (e.g., D on FIG. 7).

1. A vertical probe array comprising:
an upper guide plate;
a lower guide plate;
an array of vertical probes, wherein each of the vertical probes passes though corresponding holes in the upper and lower guide plates, wherein each of the vertical probes is mechanically elastic and electrically conductive;
wherein each of the probes is a straight conductor when not subjected to a mechanical force;
wherein the holes of at least one of the upper and lower guide plates are angled at a bias angle configured to provide a mechanical bias to the probes sufficient to define a buckling direction of each probe when the array of vertical probes is vertically compressed.

2. The vertical probe array of claim 1, wherein the holes of the upper guide plate are angled.

3. The vertical probe array of claim 1, wherein the holes of the lower guide plate are angled.

4. The vertical probe array of claim 1, wherein the holes of the upper guide plate are angled and wherein the holes of the lower guide plate are angled.

5. The vertical probe array of claim 1, wherein the bias angle is 1 degree or larger.

6. The vertical probe array of claim 1, wherein the bias angle is above a critical angle that is determined by a ratio of guide plate offset to guide plate spacing.
